(19) United States
(12) Patent Application Publication
(10) Pub. No.: US 2008/0013276 A1
(43) Pub. Date: Jan. 17, 2008

(54) SYSTEMS AND METHODS FOR IMPROVED COOLING OF ELECTRICAL COMPONENTS

(76) Inventor: Michael Pyle, Draper, UT (US)

Correspondence Address: BAKER & ASSOCIATES PLLC, 470 EAST NINTH AVENUE, SALT LAKE CITY, UT, 84103, US

(21) Appl. No.: 11/770,070

(22) Filed: Jun. 28, 2007

Related U.S. Application Data
(60) Provisional application No. 60/806,232, filed on Jun. 29, 2006.

(51) Int. Cl. H05K 7/20

(52) U.S. Cl. 361/695; 361/694

(57) ABSTRACT

One embodiment relates to an electrical component cooling system that facilitates convectional air flow. The system includes a set of electrical component boards, an inlet, an outlet, and a housing. The electrical component boards each include a plurality of electrical components and are oriented vertically. The inlet is disposed on the housing below the electrical component boards, and the outlet is disposed on the housing above the electrical component boards. The housing substantially encases the electrical component boards and further includes a plenum. The inlet enables ambient air to flow into the plenum disposed within an internal region of the housing. The plenum horizontally directs the air to locations vertically aligned with the regions between the electrical component boards to facilitate convectional air flow in the vertical direction. Heat transfer occurs between the electrical component boards and the air as it flows across the surfaces of the electrical component boards.

### RELATED APPLICATIONS

This application claims priority to U.S. provisional application Ser. No. 60/806,232 filed Jun. 29, 2006, the contents of which are incorporated by reference.

### FIELD OF THE INVENTION

The invention generally relates to systems and methods of electrical component cooling. In particular, the invention relates to systems and methods for air based cooling of integrated video and audio electrical components.

### BACKGROUND OF THE INVENTION

Audio and video components are designed to convert electrical signals into either audio or video outputs for conveying information to a user for purposes of entertainment or communication. For example, a television converts an electrical input signal into a visual image and a corresponding audible output. Improvements in technology have increased the performance of these devices so as to produce higher quality outputs. The quality of an audio or video output may be defined by the clarity or amount of undesirable signal present in the output. For example, a high quality audio output will include a minimal amount of audible noise such as static, crosstalk, etc. Likewise, a high quality video image will include a minimal amount of visual noise such as stray images, color patterns, distortion, etc.

Home entertainment has evolved from separate audio and video components to integrated multi-component systems that are used to maximize performance. For example, audio systems are designed to produce a relatively high level of audio output for purposes of listening to music or other types of audio information. Whereas, video components typically include the ability to produce both audio and video outputs. However, the audio systems of most video components generally produce a lower quality output than a corresponding dedicated audio component. Therefore, components have been developed to couple with one another so as to increase performance or provide additional functionality. Various components are commonly electrically coupled together including video output devices, audio output devices, video input devices, audio input devices, networking devices, etc.

Modern presentations utilize audible and visible information to assist in communicating concepts in an effective and efficient manner. For example, presenters often utilize Powerpoint™ presentations to include visual information that assists in communicating concepts during a presentation. Presentations may also include media clips or audio recordings. As with home entertainment, higher quality audio and video are preferable to effectively convey concepts or entertain an audience during presentations.

The performance, reliability, and/or quality level of audio and video components is affected by a multitude of variables and characteristics. Advances in electrical technology alone do not necessarily solve certain performance problems with respect to audio and video components. For example, the quality of video produced by a video output component will be significantly affected by a power supply that includes an abundance of electrical abnormalities regardless of the video technology included in the particular video output device. It is also necessary for components to operate and intercouple with one another in a simplified, seamless and reliable manner so as to be utilized to the full potential. Therefore, there is a need in the industry for systems and methods of increasing audio and video performance by incorporating technologies that maximize performance characteristics. In addition, there is a need in the industry for systems and methods that allow users to more effectively utilize audio and video components, including integration, interfaces, and operational systems.

### SUMMARY OF THE INVENTION

Embodiments of the present invention relate to systems and methods for air based cooling of integrated video and audio electrical components. One embodiment of the present invention relates to an electrical component cooling system that facilitates convectional air flow. The system includes a set of electrical component boards, an inlet, an outlet, and a housing. The electrical component boards each include a plurality of electrical components and are oriented vertically. The inlet is disposed on the housing below the electrical component boards, and the outlet is disposed on the housing above the electrical component boards. The housing substantially encases the electrical component boards and further includes a plenum. The inlet enables ambient air to flow into the plenum disposed within an internal region of the housing. The plenum horizontally directs the air to locations vertically aligned with the regions between the electrical component boards to facilitate convectional air flow in the vertical direction. Heat transfer occurs between the electrical component boards and the air as it flows across the surfaces of the electrical component boards. A second embodiment of the present invention relates to a method for air based cooling of integrated electrical components. The method includes receiving ambient air into an internal region of the housing at a location below a set of electrical component boards. Received air is horizontally directed to correspond to locations vertically aligned with regions between the electrical component boards. The directed air changes temperature as it flows past the electrical component boards. Air from the internal region is exhausted at a location above the electrical component boards. Various other well known cooling systems or methods may be incorporated or combined with embodiments of the present invention to further increase the cooling performance of a particular system or method.

Electrical components often generate heat during use. As the temperature of audio and video components elevates, the performance, quality, and lifespan of the affected components generally decreases. Conventional electrical cooling systems sense heat and rely on fans and sidewall venting systems to force air to circulate so as to cool the internal components. Unfortunately, fans alone are not sufficient to properly circulate air to effectively cool components once they reach particular heat levels. In addition, electrical fans cause audible noise and electrical voltage drops that may further affect the performance or quality of audio and video components. Conventional components generally orient electrical boards in a horizontal configuration in order to minimize vertical dimensions. Unfortunately, horizontal boards trap generated heat underneath causing dead spots, thereby impeding ventilation and allowing heat to increase. Systems and methods of the present invention overcome these limitations of conventional systems by providing embodiments for improved air based cooling.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE DRAWINGS

The following description of the invention can be understood in light of the Figures, which illustrate specific aspects of the invention and are a part of the specification. Together with the following description, the Figures demonstrate and explain the principles of the invention. The Figures presented in conjunction with this description are views of only particular—rather than complete—portions of the systems and methods of making and using the system according to the invention. In the Figures, the physical dimensions may be exaggerated for clarity. The figure numbers corresponded to the respective page number.

FIG. 1 illustrates an exploded perspective view of an air based electrical cooling system in accordance with one embodiment of the present invention;

FIG. 2A-2C illustrate schematic, rear cutaway, and perspective views of the ambient air flow cycle in an electrical cooling system in accordance with the embodiment illustrated in FIG. 1, wherein air flow is illustrated flowing substantially vertically past a plurality of vertically oriented electrical boards;

FIG. 3A illustrates a detailed perspective view of the plenum illustrated in FIG. 1;

FIG. 3B illustrates a detailed elevational view of an alternative plenum for use in an air based cooling system such as the embodiment illustrated in FIG. 1;

FIG. 4 illustrates a detailed perspective view of the outlet and upper housing surface illustrated in FIG. 1; and

FIG. 5 illustrates a flow chart of a method for air based cooling of integrated electrical components in accordance with a second embodiment of the present invention.

### DETAILED DESCRIPTION OF THE INVENTION

Embodiments of the present invention relate to systems and methods for air based cooling of integrated video and audio electrical components. One embodiment of the present invention relates to an electrical component cooling system that facilitates convectional air flow. The system includes a set of electrical component boards, an inlet, an outlet, and a housing. The electrical component boards each include a plurality of electrical components and are oriented vertically. The inlet is disposed on the housing below the electrical component boards, and the outlet is disposed on the housing above the electrical component boards. The housing substantially encases the electrical component boards and further includes a plenum. The inlet enables ambient air to flow into the plenum disposed within an internal region of the housing. The plenum horizontally directs the air to locations vertically aligned with the regions between the electrical component boards to facilitate convectional air flow in the vertical direction. Heat transfer occurs between the electrical component boards and the air as it flows across the surfaces of the electrical component boards. A second embodiment of the present invention relates to a method for air based cooling of integrated electrical components. The method includes receiving ambient air into an internal region of the housing at a location below a set of electrical component boards. Received air is horizontally directed to correspond to locations vertically aligned with regions between the electrical component boards. The directed air changes temperature as it flows past the electrical component boards. Air from the internal region is exhausted at a location above the electrical component boards. Various other well known cooling systems or methods may be incorporated or combined with embodiments of the present invention to further increase the cooling performance of a particular system or method. Also, while embodiments of the present invention are described in reference to air based cooling systems, it will be appreciated that the teachings are applicable to other fields.

The following terms are defined for purposes of utilization throughout this application:

Electrical component board—a board configured to house a plurality of electrical components, wherein the electrical components are mechanically coupled to the board and electrically coupled to one another. In addition, electrical component boards may mechanically and electrically couple with a bus or receiver to facilitate support of the board and one or more external electrical connections. One type of electrical component board is a printed circuit board also known as a PCB.

Vertical alignment—a device that is vertically aligned or positioned such that its longest dimension is oriented in a substantially vertical plane or normal to a supporting surface. For example, a telephone pole is aligned vertically.

Plenum—a module for directing air flow.

Audio input device—an electrical device configured to produce audio signals including but not limited to a receiver, tuner, a digital media player (CD, DVD, etc), a television, a computer, a gaming console, a portable media player, etc.

Audio output device—an electrical device configured to receive and broadcast audio signals in an audible format including but not limited to speakers, subwoofers, tweeters, headphones, etc.

Video input device—an electrical device configured to produce video signals including but not limited to a cable receiver, a tuner, a television, a computer, a gaming console, etc.

Video output device—an electrical device configured to receive and broadcast video signals in a visual format including but not limited to a monitor, a television, a cell phone, a portable media player, etc.

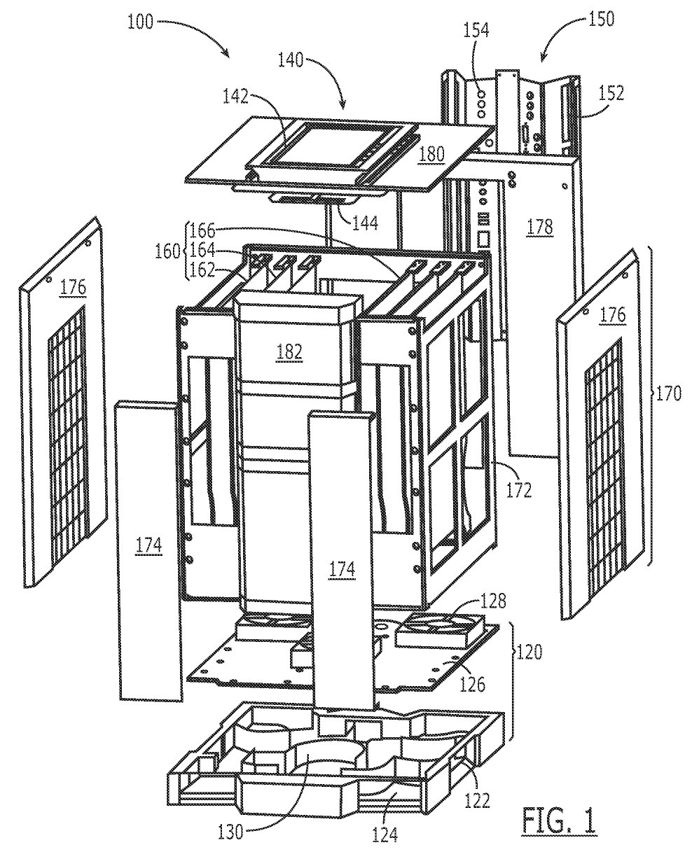

Reference is initially made to FIG. 1, which illustrates an exploded perspective view of an air based electrical cooling system in accordance with one embodiment of the present invention, designated generally at 100. The system includes a set of electrical component boards 160, a plenum 120, an outlet 140, and a housing 170. The illustrated electrical component boards 160 include six boards, three of which are designated respectively as a first, second, and fourth board 162, 164, 166. Various systems may hold as few as two electrical component boards and still incorporate the teachings of the present invention. The illustrated electrical component boards 160 include individual electrical components electrically intercoupled as a conventional printed circuit board to provide audio and/or video functionalities. Each of the electrical component boards 160 may be a conventional audio or video component without its housing, such as a DVD player, game console, DVR, etc. The electrical component boards 160 are also electrically intercoupled with one another to further provide audio and/or video functionalities. The electrical intercoupling of the individual electrical component boards 160 is configured to integrate their functionalities and includes both software and hardware integration. To facilitate the proper air flow, the electrical component boards 160 are oriented vertically with the longest axis oriented perpendicular to the supporting surface. The orientation of the boards 160 is mechanically supported by the housing 170 and more particularly by an internal chassis or racking system 172. The electrical component boards 160 may further include mounting structures so as to ensure consistent shaping among the individual boards. The internal chassis or racking system creates a particular spacing between the boards, as illustrated.

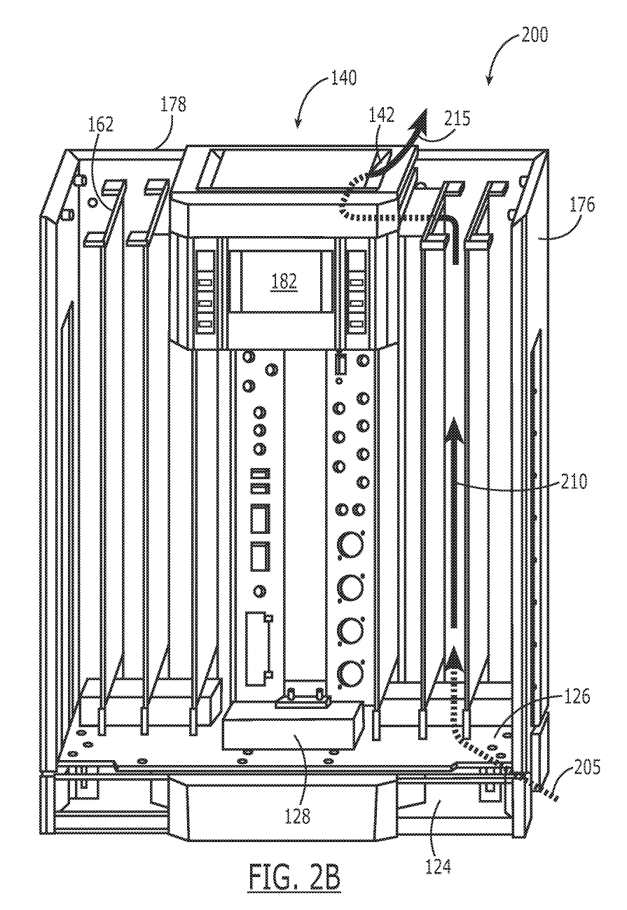

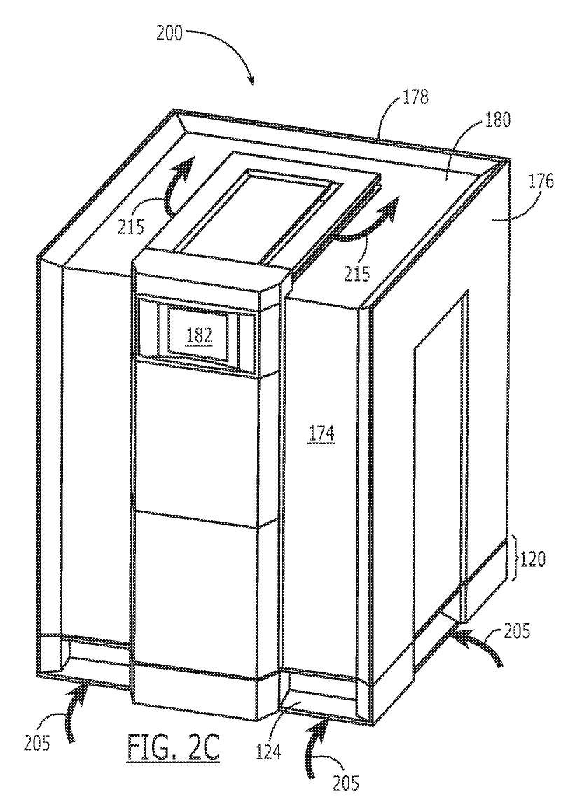

The plenum 120 is disposed below the housing 170 and the electrical component boards 160. The plenum 120 facilitates the intake and directing of ambient air for the cooling system 100. The plenum 120 includes a front inlet 124, a lateral inlet 122, a set of air guides 130, a cover 126, and a set of fans 128. The inlets 122, 124 receive ambient air from the surrounding environment and allow it to enter the system at a location vertically below the electrical component boards 160. This location of air intake is critical in the overall system's ability to utilize the natural process of convection for heat transfer. The set of air guides 130 and cover 126 create independent air flow channels that horizontally direct the air to flow to regions vertically aligned with locations corresponding to between the individual electrical component boards 160. In the illustrated embodiment, these vertically aligned locations correspond to the positioning of the fans 128. It should be noted that the fans 128 enhance the natural convection based air flow and are optional components. Therefore, even if the fans 128 are removed or malfunction, the system 100 will circulate ambient air through convection alone. In the illustrated embodiment, the fans 128 enhance the air flow by further directing the air vertically from the plenum 120 between the electrical component boards 160. Additional details and description of the plenum 120 and its associated system wide functionality and internal technology will be discussed in reference to FIGS. 3A-3B.

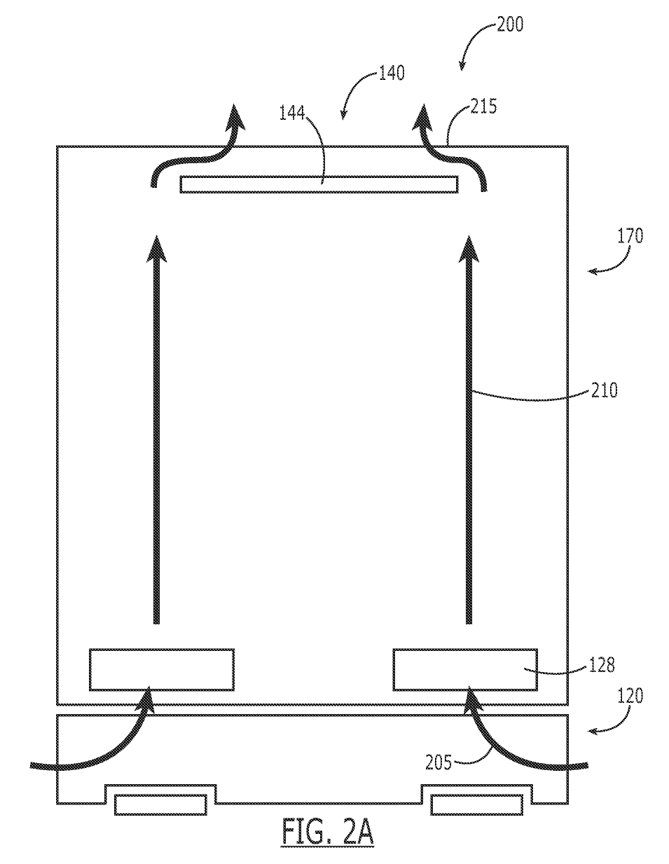

The housing 170 substantially encases and supports the electrical component boards 160 in the vertically oriented configuration illustrated and described above. The region within the housing 170 receives air flow vertically from the plenum 120, allows it to flow vertically around and between the electrical component boards 160, and then exhaust toward the outlet 140. The air flow adjacent to the electrical component boards is naturally heat affected because of the difference in heat between the ambient air received from the plenum 120 and the heat generated by the operation of the electrical component boards 160. To normalize the heat between the two, the heat from the electrical component boards 160 is released, thereby heat affecting the air. This heat affecting process causes the air to rise in both temperature and position, thereby naturally causing the vertical air flow cycle of the system 100 through convection. The air flow cycle will be illustrated and described in more detail with reference to FIGS. 2A-2C.

The housing 170 includes a plurality of panels, a set of front panels 174, a set of side panels 176, a rear panel 178, and a top panel 180. The housing 170 further includes an internal chassis 172, a front console 182, and a rear connection panel 150. The panels 174, 176, 178, 180 mechanically couple to one another and the internal chassis 172 to define and internal region in which the electrical component boards 160 are housed. The encasement of electrical components is well used in the electronics industry for purposes including dust protection, electrical isolation, and noise dampening. The front console 182 includes various electrical interconnections, human interface modules, and remote control transceiver locations. The rear connection panel 150 provides a plurality of electrical connections for input and output to the electrical component boards 160. The rear connection panel includes a frame 152 and a set of connection ports 154.

The outlet 140 is disposed on the top cover 180 of the housing 170 to facilitate the exhaust of the temperature affected air through convectional heat transfer principles. The outlet 140 is disposed above the electrical component boards 160 and at the apex of the system 100 to enable heated air to naturally rise away from the electrical component boards 160 and exhaust out of the system 100. The outlet 140 includes an internal baffle 144 and an external port 142. The temperature affected air from within the housing will flow both horizontally and vertically around the baffle 144 and out through the external port 144 so as to be recombined with the ambient air, thereby creating an air flow cycle.

Reference is next made to FIG. 2A-2C, which illustrate schematic, rear cutaway, and perspective views of the ambient air flow cycle in an electrical cooling system in accordance with the embodiment illustrated in FIG. 1, designated generally at 200. FIG. 2A-2C illustrate alternative views of the air flow cycle 200 in the system 100. Ambient air flows into one or more of the inlets 124, 122, and both horizontally and vertically through the plenum 120 to the vertically aligned locations, represented by air flow arrow 205. The air flow is then optionally enhanced by the set of fans 128 and allowed to flow vertically between and around the electrical component boards 160 (see FIG. 2C) within the housing 170, represented by air flow arrow 210. The air then flows horizontally and vertically around the baffle 144 and out the outlet 140 so as to be recombined with the ambient air, represented by air flow arrow 215.

Reference is next made to FIG. 3A, which illustrates a detailed perspective view of the plenum illustrated in FIG. 1, designated generally at 120. The plenum 120 comprises multiple air inlets including orthogonally positioned front 124 and lateral inlets 122. The orthogonal disposition of the inlets 122, 124 permits increased air flow and ensures that sufficient ambient air is able to enter the plenum 120. Conventional electrical systems often have a single air inlet which may be obstructed depending on the orientation and positioning of the system in relation to walls and other objects. Therefore, the orthogonal disposition of the inlets 122, 124 also creates an air flow intake redundancy. In the illustrated plenum 120, inlets are disposed on three of the four lateral sides to maximize possible air flow. The fourth side of the plenum 120 without an inlet corresponds to the rear of the system and is vertically aligned with the rear connection panel 150 (see FIG. 1). The plenum 120 receives ambient air and directs it to particular vertically aligned locations 132 for optimal heat transfer. The detailed view illustrates the curved nature of the air flow guides 130 designed to minimize resistance. The air flow guides 130 and the cover 126 (not shown) create the channels the direct the air to the vertically aligned locations 132. The vertically aligned locations 132 two dimensionally correspond to openings in the cover 126 (not shown) and individual fans 128 to permit and enhance vertical air flow in the system 100 respectively.

Reference is next made to FIG. 3B illustrates a detailed elevational view of an alternative plenum design, designated generally at 320. The illustrated plenum 320 may function in a sandwich configuration with a mating cover member (not illustrated) that also includes a pattern of corresponding air flow guides and channels. The illustrated plenum 320 includes frontal and lateral inlets 324, 322, numerous air flow guides 330, vertically aligned locations 332, support members 334, and a rear region 350. The plenum 320 is significantly different from the plenum 120 in the shape and nature of the air flow guides 330. It was determined that air flow redirection could be enhanced through the use of numerous small air flow guides 330 versus larger curved air flow guides 130. The air flow guides 330 still function in conjunction with a cover (not illustrated) to create channels that direct air flow toward the vertically aligned locations 332. The inlets 324, 322 include channel members that direct air into the plenum 320 rather than allowing any type of turbulence. In addition, the plenum 120 includes support members 334 for supporting the plenum 320 above a supporting surface. The rear region 350 again corresponds to the rear of the associated system and is vertically aligned with a rear connection panel. The illustrated plenum 320 may be used to replace plenum 120 in the system 100 illustrated in FIG. 1 or may be utilized in an alternative system.

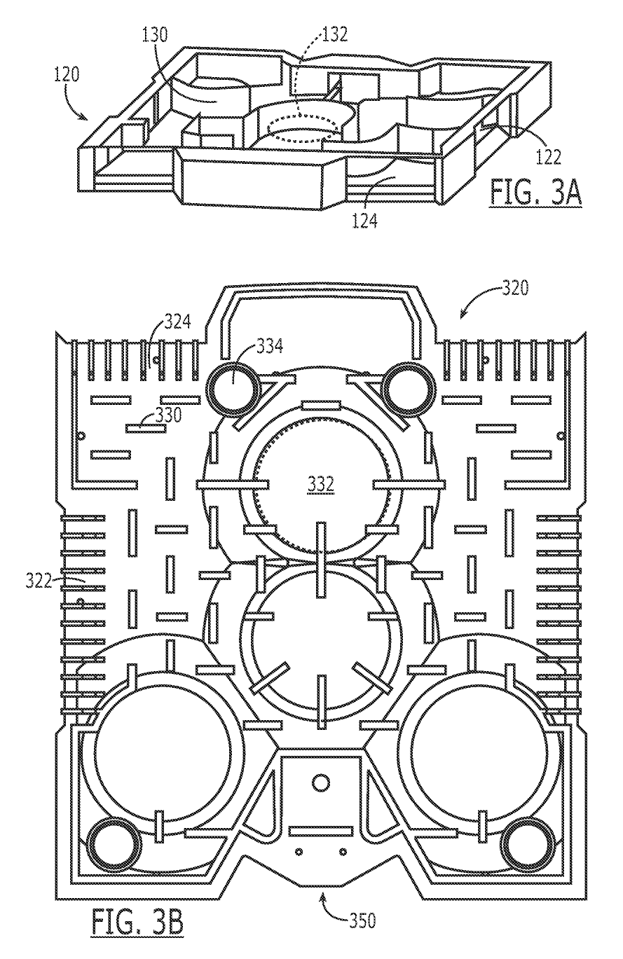

Reference is next made to FIG. 4, which illustrates a detailed perspective view of the outlet and upper housing surface illustrated in FIG. 1, designated generally at 140. The outlet 140 is disposed on the top panel 180 of the housing 170 (see FIG. 1). The outlet 140 includes an internal baffle 144 (see FIG. 1), an external port 142, and a secondary external port 146. The outlet 140 is designed to enable heat affected air to flow out of the system 1 00. The heat affected air may flow out of either the external port 142 or the secondary external port 146. Various other outlet 140 designs may be utilized in conjunction with the system 100 and remain consistent with the present invention.

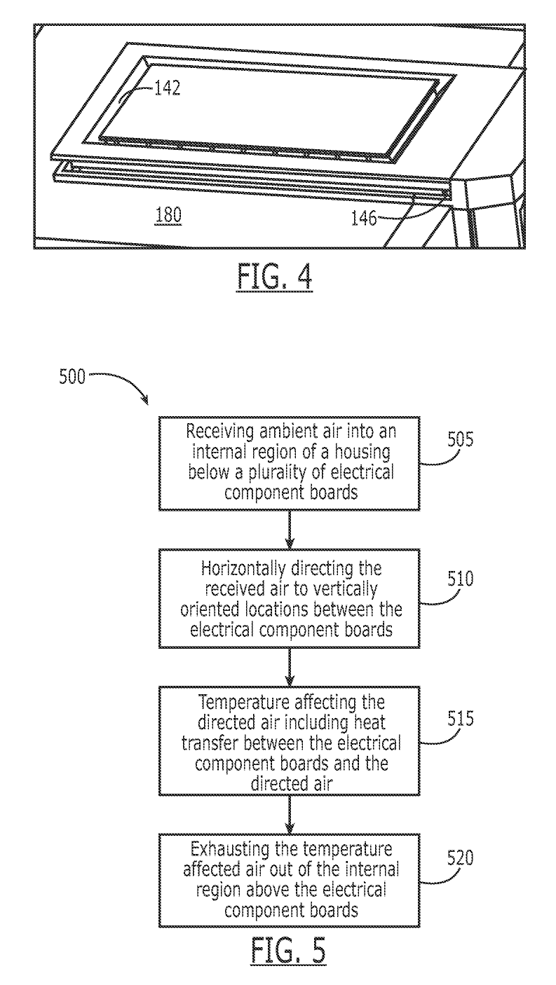

Reference is next made to FIG. 5, which illustrates a flow chart of a method for air based cooling of integrated electrical components, designated generally at 500. The method includes initially receiving ambient air into an internal region of a housing below a plurality of electrical component boards, act 505. The received air is then horizontally directed to vertically oriented locations between the electrical component boards, act 510. The directed air is then temperature affected as is flows adjacent to the plurality of electrical component boards including heat transfer between the electrical component boards and the directed air, act 515. The temperature affected air is then exhausted out of the internal region above the electrical component boards, act 520.

Various other embodiments have been contemplated, including combinations in whole or in part of the embodiments described above.

What is claimed is:

1. An air based cooling system for integrated electrical components comprising:
a plurality of electrically interconnected electrical component boards, wherein the electrical component boards are oriented in a substantially vertical configuration;
an inlet disposed vertically below the electrical component boards, wherein the inlet is configured to receive ambient air;
an outlet disposed vertically above the electrical component boards, wherein the outlet is configured to exhaust air that is temperature affected by the electrical component boards; and
a housing substantially encasing the electrical component boards, wherein the housing mechanically supports the electrical component boards in the substantially vertical configuration, and wherein the inlet is disposed on at least one lateral surface of the housing, and wherein the outlet is disposed on an upper surface of the housing, and wherein the relative positioning of the inlet, outlet, and electrical component boards facilitates convention based air flow from the inlet across the electrical components boards and out the outlet.

2. The system of claim 1, wherein the housing further includes a plenum disposed vertically below the electrical component boards, and wherein the plenum horizontally directs the received ambient air to at least one horizontal location that is vertically aligned between at least two of the electrical component boards, and wherein the inlet is disposed on the plenum.

3. The system of claim 2, wherein the plenum includes a plurality of inlets disposed on independent orthogonal surfaces of the plenum, and wherein the plenum includes a plurality of independent air flow channels independently corresponding to each of the plurality of inlets.

4. The system of claim 2, wherein plenum includes at least one fan configured to assist air flow through the system.

5. The system of claim 4, wherein the at least one fan includes a variable speed controller that is configured to adjust the fan speed according to the temperature of the electrical component boards.

6. The system of claim 1, wherein the outlet is disposed at the vertical apex of the air based cooling system to facilitate convection air flow of air that is temperature affected by the electrical component boards.

7. The system of claim 1, wherein the air that is temperature affected by the electrical component boards includes heat transfer between the electrical component boards and the received ambient air.

8. The system of claim 1, wherein the outlet includes a multi-directional channel that horizontally and vertically directs the temperature affected air within the encasement of the housing.

9. The system of claim 1, wherein the outlet is substantially horizontally two dimensionally centered on the upper surface of the housing.

10. The system of claim 1, wherein each of the electrical component boards include at least one of an audio input, video input, audio output, and video output.

11. An air based cooling system for integrated electrical components comprising:
a plurality of electrically interconnected electrical component boards, wherein the electrical component boards are oriented in a substantially vertical configuration;
an inlet disposed vertically below the electrical component boards, wherein the inlet is configured to receive ambient air;
an outlet disposed vertically above the electrical component boards, wherein the outlet is configured to exhaust air that is temperature affected by the electrical component boards; and
a housing substantially encasing the electrical component boards, wherein the housing mechanically supports the electrical component boards in the substantially vertical configuration, and wherein the inlet is disposed on at least one lateral surface of the housing, and wherein the outlet is disposed on an upper surface of the housing, and wherein the relative positioning of the inlet, outlet, and electrical component boards facilitates convention based air flow from the inlet across the electrical components boards and out the outlet, wherein the housing further includes a plenum disposed vertically below the electrical component boards, and wherein the inlet is disposed on the plenum, and wherein the plenum horizontally directs the received ambient air to at least one horizontal location that is vertically aligned between at least two of the electrical component boards, wherein the plenum includes a plurality of inlets disposed on independent orthogonal surfaces of the plenum, and wherein the plenum includes a plurality of independent air flow channels independently corresponding to each of the plurality of inlets.

12. A method for air based cooling of integrated electrical components comprising the acts of:
providing a plurality of vertically oriented electrical component boards substantially encased within a housing;
receiving ambient air flow into an internal region of the housing at a location vertically below the electrical component boards;
horizontally directing the received air to at least one horizontal location vertically corresponding to a region between and below at least two of the electrical component boards;
temperature affecting the directed air including heat transfer between the electrical component boards and the directed air; and
exhausting the temperature affected air out of the internal region at a location vertically above the electrical component boards.

13. The method of claim 12, wherein the act of receiving ambient air flow into an internal region of the housing at a location vertically below the electrical component boards includes receiving ambient air flow from a plurality of substantially orthogonal inlets.

14. The method of claim 12, wherein the act of horizontally directing the received air to at least one horizontal location vertically corresponding to a region between and below at least two of the electrical component boards includes independently channeling received air from a plurality of substantially orthogonal inlets.

15. The method of claim 12, further including the act of fan assisting the received, directed, and exhausted air flow.

16. The method of claim 15, wherein the act of fan assisting the received, directed, and exhausted air flow includes correlating the fan assistance with the temperature of the electrical component boards.

17. The method of claim 12, further including the act of providing convection based air flow across the electrical component boards.

18. The method of claim 12, wherein the act of temperature affecting the directed air including heat transfer between the electrical component boards and the directed air includes flowing the directed air across the surfaces of the electrical component boards.

19. The method of claim 12, wherein the act of exhausting the temperature affected air out a location vertically above the electrical component boards includes horizontally and vertically directing the temperature affected air through a multi-directional channel.

20. The method of claim 12, further including the act of cycling exhaust air into an ambient environment before receiving the ambient air flow.
